(19) United States
(12) Patent Application Publication
(10) Pub. No.: US 2010/0244042 A1
(43) Pub. Date: Sep. 30, 2010

(54) Group III nitride compound semiconductor light emitting element and manufacturing method thereof

(75) Inventors: Yoshiki Saito, Aichi-ken (JP); Yasuhisa Ushida, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/659,763

(22) Filed: Mar. 19, 2010

(30) Foreign Application Priority Data
Mar. 30, 2009 (JP) P2009-081148

(51) Int. Cl. H01L 33/44; H01L 33/30; H01L 21/20

(52) U.S. Cl. 257/76; 257/98; 438/29; 257/E33.061; 257/E21.09

(57) ABSTRACT

A group III nitride compound semiconductor light emitting element comprising: a first layer which is a single crystal layer of a group III nitride compound semiconductor, the first layer formed on the buffer layer and including a threading dislocation; a second layer of a group III nitride compound semiconductor formed on the first layer, the second layer including a pit and a flat portion, wherein the pit continuing from the threading dislocations and having a cross section parallel to the substrate expanding in a growth direction of the second layer; a luminescent layer including a flat portion and a pit corresponding to those of the second layer. The indium concentration in the pit of the luminescent layer is smaller than that in the flat portion of the luminescent layer. A luminescent spectrum width of thereof is expanded as compared to a case where the pit does not exist.

### CROSS REFERENCE TO RELATED APPLICATIONS

The present application claims priority from Japanese Patent Application No. 2009-081148 filed on Mar. 30, 2009, and the subject matter of which is incorporated herein by reference.

### TECHNICAL FIELD

The present invention relates to a group III nitride compound semiconductor light emitting element and manufacturing method thereof. In this application, a group III nitride compound semiconductor means a semiconductor described by the chemical formula AlₓGayIn_{1-x-y}N (0≦, y, x+y≦1), the same which is p-doped or n-doped by an arbitrary impurity, and the same where a part of the group III element or the group V element is substituted by B or Ti, and P, As, Sb, and Bi.

### BACKGROUND

As light emitting devices using a group III nitride compound semiconductor element become prevalent, applications of such devices to an ordinary illumination is developing. For example, as a substitute of a white color lamp, the group III nitride compound semiconductor light emitting element has been used. Mass-produced such white color illumination devices using the group III nitride compound semiconductor element are a RGB multi white type and a phosphors combined type.

The multi white type light emitting device emits white light by mixing light emitted from a blue color, a green color, and red color light emitting elements. For example, the blue color light emitting element and the green color light emitting element are the group III nitride compound semiconductor elements, and the red color light emitting element is GaAs series light emitting element. As an another type of light emitting device, it is proposed to substitute an integral type light emitting element for the two or three of the light emitting elements of the multi white type. In the integral type, a plurality of luminescent layers are stacked in a vertical direction.

The phosphors combined type emits white light by mixing yellow light and blue light with a yellow phosphors and a blue light emitting element. The blue light emitting element emits visual blue light and ultraviolet light. The yellow phosphors convert ultraviolet light emitted from the blue light emitting element into the yellow light. The yellow light is mixed with the blue light emitted from the blue light emitting element so as to make white light.

JP-A-2005-129905 and JP-A-2008-218746 are related arts of the present application.

The multi white type light emitting device has high production costs since it requires three light emitting elements to configure a one white light illumination and has a complicated stacking structure to form the device integrally. On the other hand, the phosphors may become a tough option since the choice of the elements and compounds not environmentally friendly is expected to become difficult for the phosphors.

According to the related art JP-A-2005-129905, during forming a luminescent layer, it is necessary to form asperities on the surface just under the luminescent layer by etching with a mask in order to form regions emitting light of different wavelength. This technique requires the increased number of works and high production costs since this technique needs a mask forming and an etching in a separate machine during the epitaxial growth, as compared to a conventional manufacturing method of a light emitting element.

According to the related art JP-A-2008-218746, a blue light emitting element is configured. The inventors of the present application found an important fact after industrious examination.

### SUMMARY

The exemplary embodiments of the present invention provides light emitting elements, which emit white color light or another color light, by a facile method without increase in the number of the works and production costs.

The first aspect of the exemplary embodiments of the present invention is a group III nitride compound semiconductor light emitting element, which having an luminescent layer formed from a group III nitride compound semiconductor containing at least indium, comprising: a substrate; a buffer layer formed on the substrate; a first layer which is a single crystal layer of a group III nitride compound semiconductor, the first layer formed on the buffer layer and including a threading dislocation; a second layer of a group III nitride compound semiconductor formed on the first layer, the second layer including a pit and a flat portion, wherein the pit continuing from the threading dislocation, formed during the second layer growth, and having a cross section parallel to the substrate expanding in a growth direction of the second layer; a luminescent layer formed on the second layer while along the pit of the second layer and the flat portion of the second layer so as to form a flat portion of the luminescent layer and a pit of the luminescent layer, and an indium concentration in the pit of the luminescent layer smaller than an indium concentration in the flat portion of the luminescent layer; and a third layer of a group III nitride compound semiconductor formed on the luminescent layer.

The luminescent layer means a layer emits light based on recombination of injected electrons and holes. Therefore, the luminescent layer includes so called active layer. The light emitting element of the exemplary embodiments of the present invention includes a light emitting diode (LED) and a laser. A preferable range of the thickness of the luminescent layer is equal to or more than 1 nm and equal to or less than 10 nm for each well layer of the multi quantum well structure in a case where the multi quantum well structure is adopted.

The flat portion of the second layer is a surface portion of the second layer parallel to the primary surface of the substrate. In other words, the flat portion of the second layer is a surface portion of the second layer other than the pit.

The flat portion of the luminescent layer is a flat portion corresponding to the upside of the flat portion of the second layer. The pit of the luminescent layer is a portion formed corresponding to the pit of the second layer.

The luminescent spectrum whose spectrum width is expanded as compared to a luminescent spectrum of a case where the pit does not exist, means such a luminescent spectrum that whose spectrum width is expanded due to overlap of two luminescent spectrums: the one originated from a flat portion and the other originated from a pit where the indium concentration is small. As the expansion of the half value width, contrary to the half value width less than 100 nm for ordinal homochromatic LEDs, the exemplary embodiments of the present invention have a half value width more than 120 nm, and further more than 150 nm. That is, the half value width of the exemplary embodiments is more than 1.2 times or 1.5 times of the half value width of the luminescent spectrum derived only from the flat portion. For example, in the related art JP-A-2005-129905 (paragraph 38), there is no change in the luminescent wavelength depending on the existence of the pit and there is no expansion of the luminescent spectrum. The exemplary embodiments of the present invention form the pit deeply and densely so as to affect the luminescent spectrum. The exemplary embodiments of the present invention are characterized in that the threading dislocation penetrating the first layer and originated from the buffer layer is transformed into a pit whose cross section parallel to the substrate expands in the growth direction in the second layer. The word “pit” describes any object originated from a tiny cylindrical threading dislocation and having an inclined surface. Therefore, the word “pit” does not limit its meaning to a specific object.

The pit whose cross section expands is formed during a growth of the second layer. The pit is not formed by etching while terminating the epitaxial growth of the second layer.

As the substrate, an inorganic crystal substrate such as sapphire, silicon (Si), silicon carbide (SiC), spinel (MgAl2O4), zinc oxide (ZnO), and magnesium oxide (MgO), and a group III-V compound semiconductor such as gallium phosphate and gallium arsenic. A preferable manufacturing method of the group III compound semiconductor layer is metal organic chemical vapor deposition (MOCVD) or metal organic vapor epitaxy (MOVPE). Molecular beam epitaxy (MBE) and various kinds of growth methods may be used for the growth of the group III compound semiconductor layer.

The buffer layer is formed in order to relax the lattice mismatch between the substrate and the group III compound semiconductor layer. The buffer layer is not a single crystal layer but an amorphous layer, a polycrystal layer, and a layer mixture of polycrystal and microlite. As the buffer layer, AlₓGa_{y}In_{1-x-y}N (0≦x≦1, 0≦y≦1, 0x+y≦1) formed in low temperature is preferable. AlₓGa₁₋ₓN (0≦x≦1) is more preferable for the buffer layer. The buffer layer may be a single layer and may be a multi layered structure of different composition layers. A manufacturing method of the buffer layer may be a method performed in a low temperature range equal to or more than 380 and equal to or less than 600 degrees Celsius, and may be MOCVD in a temperature range equal to or more than 1000 and equal to or less than 1180 degrees Celsius. In a case where the buffer layer formed in a low temperature range, the temperature range equal to or more than 380 and equal to or less than 420 degrees Celsius is preferable for AlN buffer layer and the temperature range equal to or more than 500 and equal to or less than 600 degrees Celsius for GaN buffer layer.

Also it is possible to form a AlN buffer layer by a reactive sputtering with a DC magnetron sputtering machine and high purity aluminum and nitrogen gas as materials. With similar method, a buffer layer described by the general formula AlₓGa_{y}In_{1-x-y}N (0≦x≦1, 0≦y≦1, 0≦x+y≦1, composition ratio is arbitrary) can be formed. Also, deposition, ion plating, laser ablation, and ECR may be used. The temperature range equal to or more than 200 and equal to or less than 600 degrees Celsius is preferable for a buffer layer formed by physical deposition. Especially, the temperature range equal to or more than 300 and equal to or less than 600 degrees Celsius is preferable, and the temperature range equal to or more than 350 and equal to or less than 450 degrees Celsius is more preferable. In a case where the physical deposition such as sputtering is adopted, there is a method that alternately forming a GaN layer and a AlₓGa₁₋ₓN layer. There is another method that forms layers of same composition alternately in different temperature ranges, one of which is equal to or less than 600 degrees Celsius and the other of which is equal to or more than 1000 degrees Celsius. Of course these methods can be combined and more than three kinds of AlₓGa_{y}In_{1-x-y}N (0≦x≦1, 0≦y≦1, 0≦x+y≦1) can be stacked for the multi layered structure. Generally, the buffer layer is an amorphous layer and the middle layer is a single crystal layer. As a one unit of the pair of the buffer layer and the middle layer, the unit can be repetitively formed in an arbitrary number of times. The more the number of the repeat increases, the more the crystalline quality is improved.

Also it is possible to form a main group III compound semiconductor layer on a first buffer layer grown on a second buffer layer. The first buffer layer is grown at a high temperature after the second buffer layer is grown at a low temperature.

The buffer layer is formed in order to control the density of the threading dislocations which reach the second layer through the first layer grown on the buffer layer. The density of the threading dislocations which reach the second layer through the first layer can be controlled by the growth temperature and the thickness of the buffer layer. The controllable range of the density of the threading dislocations is almost 10⁶ to 10¹¹/cm² and preferably 10⁸ to 10¹⁰/cm². The thickness of the buffer layer is equal to or more than 30 and equal to or less than 3000 Å, preferably equal to or more than 30 and equal to or less than 400 Å, and more preferably equal to or more than 30 and equal to or less than 300 Å.

An area of the opening of the pits formed in the luminescent layer can be controlled by the thickness of the second layer. Also, the indium concentration in the pits of the luminescent layer and in the flat portion of the luminescent layer can be controlled by the growth temperature and the amount of indium supply during the growth. The preferable growth temperature range for the luminescent layer is equal to or more than 600 and equal to or less than 900 degrees Celsius and indium composition in the group III element for the flat portion is equal to or more than 0.05 and equal to or less than 0.5 in order to expand the luminescent spectrum.

The second aspect of the exemplary embodiments of the present invention is the luminescent spectrum has at least two peaks. In other words, the luminescent spectrum has a plurality of peaks. For example, that is a luminescent spectrum of two-humped shape including one peak at a wavelength of light emitted from the flat portion of the luminescent layer and the other one peak at a wavelength of light emitted from the pit of the luminescent layer. In a case where there are two peaks in the luminescent spectrum, color mixing in a visible wavelength range is possible if the difference between the two peaks is equal to or more than 50 nm and equal to or less than 150 nm. In this case, it is preferable that the luminescent intensities of two peaks are substantially same. If one of the luminescent intensity is larger than the other, it is preferable that the larger one is within the 1.5 times of the smaller one and more preferably within the 1.2 times of the smaller one.

The third aspect of the exemplary embodiments of the present invention is that the second layer is gallium nitride. Between the second layer and the luminescent layer, there may be a single layer or a plurality of other layers of different materials such as a clad layer. In this case, it is important that such layers as the clad layer should elongate the pits from the second layer to the interface between the luminescent layer and the other layers.

The luminescent layer may be a single quantum well structure and may be a multi layered quantum well structure. The third layer maybe a single layer or a plurality of layers of different materials such as a clad layer and a contact layer.

The second layer of gallium nitride is facile to control or process after the growth. Contrary, a layer including indium is not easy to control its composition. Gallium nitride is preferable because it is necessary to keep the crystalline quality while forming the pit.

The fourth aspect of the exemplary embodiments of the present invention is that the primary surface of the flat portion of the second layer is C-surface, and the side surface forming the pit is a facet crossing the C-surface at an angle other than normal angle.

The fifth aspect of the exemplary embodiments of the present invention is that the facet is (10-11) surface.

In the fourth and fifth aspects, the primary surface of the flat portion of the second layer may not be the C-surface and the side surface forming the pits may not be a facet which indicates a low index surface. The facet may not be the (10-11) surface.

The sixth aspect of the exemplary embodiments of the present invention is that the flat portion of the luminescent layer emits green color light or red color light, and the pit of the luminescent layer emits violet color light or blue color light. The flat portion of the luminescent layer is a portion above the flat portion of the second layer. The pit of the luminescent layer is a portion above the pit of the second layer.

The seventh aspect of the exemplary embodiment of the present invention is that the luminescent color of the luminescent layer is white.

The eighth aspect of the exemplary embodiments of the present invention is a manufacturing method of a group III nitride compound semiconductor light emitting element, which having a luminescent layer formed from a group III nitride compound semiconductor including at least indium, comprising: forming a buffer layer on a substrate; forming a first layer on the buffer layer, the first layer being a single crystal layer of a group III nitride compound semiconductor, and including a threading dislocations; forming a second layer of a group III nitride compound semiconductor including a pit and a flat portion, the pit continuing from the threading dislocations, a cross section of the pit parallel to the substrate expanding in a growth direction of the second layer; forming a luminescent layer on the second layer while along the flat portion of the second layer and the pit of the second layer, the luminescent layer including a flat portion and a pit; expanding a luminescent spectrum width as compare to a luminescent spectrum width of a case where pit does not exist by reducing a indium concentration in the pit of the luminescent layer as compared to a indium concentration in the flat portion of the luminescent layer; and forming a third layer of a group III nitride compound semiconductor on the luminescent layer:

The manufacturing method of the eighth aspect is characterized in that the threading dislocations originated from the buffer layer are transformed into the pits in the second layer so that the cross section of the pit parallel to the surface expands in the growth direction. The word “pit” describes an arbitrary object originated from a tiny cylindrical threading dislocation and having an inclined surface. Therefore, the word “pit” does not limit its meaning to a specific object. The pit whose cross section expands is formed during the growth of the second layer. The pit is not formed by etching while terminating the epitaxial growth of the second layer.

The expanded amount of the luminescent spectrum of the light emitting element is determined by the product of the density of the threading dislocation in the second layer and the averaged area of the pit and the thickness of the luminescent layer (well layer).

The density of the threading dislocations in the second layer can be controlled by the thickness of the buffer layer and the temperature growth, and the area of the pit can be controlled by the thickness of the second layer and the growth temperature. These are explained in the detailed description of the exemplary embodiments.

The ninth aspect of the exemplary embodiments of the present invention is that the growth temperature for the second layer is equal to or less than 1000 degrees Celsius. The growth temperature for the second layer is preferably equal to or more than 700 degrees Celsius and equal to or less than 1000 degrees Celsius. If the growth temperature for the second layer is less than 700 degrees Celsius, the crystalline quality of the second layer is so deteriorated that the light emitting element does not obtain enough functionality and the characteristics of the light emitting elements becomes not uniform. The temperature range equal to or more than 800 and equal to or less than 970 degrees Celsius is preferable for the growth of the second layer, and the temperature range equal to or more than 850 and equal to or less than 950 degrees Celsius is more preferable for the growth of the second layer.

Especially, in a case where the second layer is GaN, the growth temperature for the second layer is equal to or more than 800 degrees Celsius and equal to or less than 1000 degrees Celsius, is preferably equal to or more than 850 degrees Celsius and equal to or less than 970 degrees Celsius, and is more preferably equal to or more than 870 degrees Celsius and equal to or less than 950 degrees Celsius.

On the other hand, in case where the second layer contains indium, the growth temperature for the second layer is equal to or more than 700 degrees Celsius and equal to or less than 900 degrees Celsius, is preferably equal to or more than 750 degrees Celsius and equal to or less than 870 degrees Celsius, and is more preferably equal to or more than 770 degrees Celsius and equal to or less than 850 degrees Celsius.

Above described growth methods are for expanding the cross section of the pit parallel to the substrate in the growth direction. Another growth condition may be used for limiting the expansion of the cross section in addition to the above described growth methods. Although the V/III ratio is relatively small in the so called vertical growth where the flat C-surface is formed, the exemplary embodiments of the present invention preferably have a relatively large V/III ratio in order to enhance the lateral growth. In a case where the V/III ratio is made relatively large by MOVPE, the V/III ratio is equal to or more than 2000 and equal to or less than 40000, is preferably the V/III ratio is equal to or more than 5000 and equal to or less than 40000, and is more preferably the V/III ratio is equal to or more than 5000 and equal to or less than 10000. In a case where the V/III ratio is set to a conventional value, the V/III ratio is equal to or more than 500 and equal to or less than 2000.

The tenth aspect of the exemplary embodiments of the present invention is that the second layer is gallium nitride.

The eleventh aspect of the exemplary embodiments of the present invention is that the growth temperature of the luminescent layer is equal to or more than 600 degrees Celsius and equal to or less than 900 degrees Celsius. Accordingly, it is possible to reduce the indium composition ratio in the pit as compare to the flat portion so that the luminescent spectrum expands and has two peaks. In a case where a multi layered quantum well structure is adopted, a preferable range of the thickness is equal to or more than 1 nm and equal to or less than 10 nm for each well layer of the luminescent layer.

When the second layer, which is the under layer of the luminescent layer contains at least indium, has a pit whose cross section parallel to the substrate expands in the growth direction, the flat portion and the pit of the luminescent layer emit light of different wavelength respectively because of the difference in the indium concentration in the flat portion and the pit. In other words, since the flat portion of the luminescent layer has a predetermined indium concentration and the pit of the luminescent layer has a relatively low indium concentration, there are the luminescent peak at a certain wavelength for the flat portion of the luminescent layer and the luminescent peak at a shorter wavelength than that of the flat portion of the luminescent layer for the pit of the luminescent layer.

Accordingly, the light emitting element of the exemplary embodiments of the present invention has a luminescent spectrum whose spectrum width is expanded relative to that of a case where the pit does not exist.

If the flat portion of the luminescent layer emits for example green color light or red color light and the pits of the luminescent layer emits for example violet color light or blue color light, the white color light emitting element is provided.

In order to manufacture such a light emitting element, the threading dislocation originated from the buffer layer is transformed into a pit in the second layer through the first layer while the buffer layer, the first layer, and the second layer are grown on the substrate in this order. Accordingly, the flat portion of the luminescent layer obtains a predetermined indium concentration since the epitaxial growth speed is fast. The pit of the luminescent layer obtains a low indium concentration since the epitaxial growth is slow.

Thus, the indium composition in the luminescent layer and the area ratio between the total area of the inclined surface of the pit and the area of the flat portion, it is possible to control the luminescent wavelength based on the indium composition in the flat portion of the luminescent layer, the luminescent wavelength of the pit of the luminescent layer, and the ratio between the luminescent intensity of the flat portion and the pit. Therefore, for example, the white color light emitting element can be provided by a facile manufacturing method.

As described later, formation of the facet in the layer just under the luminescent layer can be precisely controlled. In other words, when the group III compound semiconductor layer is epitaxially grown at a temperature equal to or less than 1000 degrees Celsius or equal to or more than 900 degrees Celsius, the epitaxial growth develops while forming a plurality of hexagonal cone like recesses having the (10-11) surface on the surface thereof. The digit with overbar means a negative Miller index. FIG. 1 shows a perspective view showing (10-11) surface of a unit cell of a hexagonal crystal. In FIG. 1, a unit cell is described as a hexagonal pillar with broken lines and a1, a2, a3, and c are crystal axes. The (10-11) surface is for example a surface including a one edge of the regular hexagon bottom surface of the unit cell and a diagonal line of the top surface parallel to the one edge of the bottom surface.

The above described facet is originated from a crystal defect, especially a threading dislocation in the first layer of a high temperature single crystal layer. The crystal defect in the first layer is continued from a crystal defect in the buffer layer while the first layer is epitaxially grown at high temperature after forming the buffer layer on the hetero-substrate.

In order to make a large number of origins for the facets in the second layer, it is preferable to make the buffer layer poly-crystal so as to contain a lot of crystal defects. In this stage, it is preferable to make the buffer layer thicker.

It is possible to change the size of the facet in the second layer by making the thickness of the second layer thicker while epitaxially growing the second layer at a temperature equal to or less than 1000 degrees Celsius and equal to or more than 900 degrees Celsius.

In order to form the facet in the second layer, other arbitrary layer may be inserted between the luminescent layer and the second layer (The second layer is epitaxially grown at a temperature equal to or less than 1000 degrees Celsius and equal to or more than 900 degrees Celsius). In this case, it is necessary that the facet exists at least in the layer just under the luminescent layer.

According to the aspects of the exemplary embodiments of the present invention, it is possible to control the number and the area of facets in the second layer only by the temperature control and the thickness control during the epitaxial growth. This advantage means that epitaxial growth can be performed without termination caused by the process performed at the outside of the epitaxial growth machine such as a resist application for a mask formation and a lithographic exposure. Therefore, a white color light emitting element can be manufactured easily with low manufacturing cost as compare to the JP-A-2005-129905.

### BRIEF DESCRIPTION OF DRAWINGS

FIG. 1 is a perspective view showing (10-11) surface of a unit cell of a hexagonal crystal.

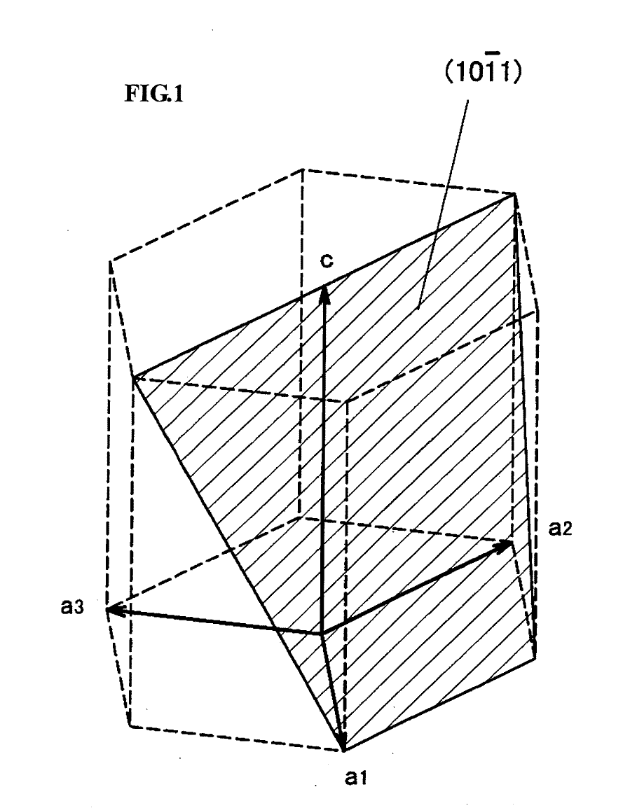

FIG. 2A is an AFM image of a GaN surface of a comparative example formed at 1100 degrees Celsius.

FIG. 2B is an AFM image of a GaN second surface of an exemplary embodiment formed at 900 degrees Celsius.

FIG. 3 is a bird's eye view of the GaN sample of the exemplary embodiment show in FIG. 2B.

FIG. 4A is an AFM image of a GaN second surface formed on a buffer layer of 200 Å thickness.

FIG. 4B is an AFM image of a GaN second surface formed on a buffer layer of 300 Å thickness.

FIG. 5 is a cross sectional view of a group III nitride compound semiconductor element 100 according to the exemplary embodiment.

FIG. 6 is a graph showing a luminescent spectrum of the group III nitride compound semiconductor element 100.

### DETAILED DESCRIPTION OF THE EXEMPLARY EMBODIMENTS

In the exemplary embodiments of the present invention, arbitrary conventional techniques can be used for manufacturing of the group III nitride compound semiconductor element.

It is possible to control the number of crystal defects as the origin of the facet by adjusting the thickness of the buffer layer in a range equal to or more than 50 and equal to or less than 500 Å, for example.

It is possible to control the size of each facet by adjusting the thickness of GaN layer in a range equal to or more than 500 nm and equal to or less than 6 μm, for example in a case where the GaN layer forms facets as the second layer.

For a single luminescent layer or a well layer of a single or multi quantum well structure, which emit light, it is preferable to set the indium composition in a range equal to or more than 0.05 and equal to or less than 0.5. Especially, it is preferable to set the indium composition in a range equal to or more than 0.3 and equal to or less than 0.5 in order to obtain a white color light emitting element.

### [With Respect to Forming Facets]

As an initial experiment, it is confirmed that the number (density) and the size of pits can be controlled by the exemplary embodiments of the present invention. In all the explanation below, metal organic vapor phase epitaxy is used for crystal growths.

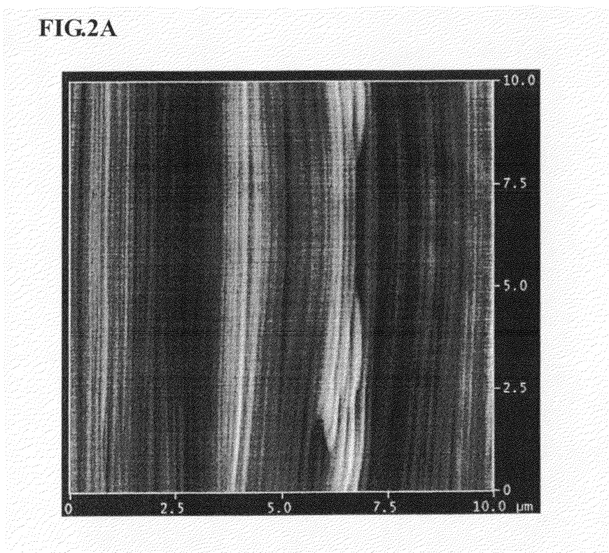

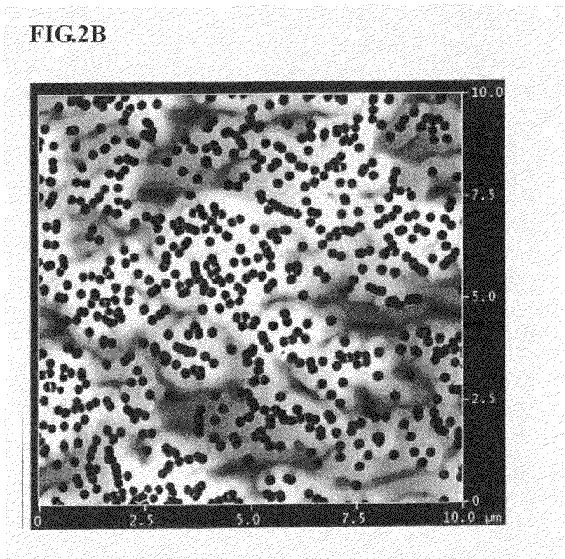

FIG. 2A is an atomic force microscope (AFM) image of a surface of an n-type GaN layer (the first layer). The n-type GaN layer is formed by forming a silicon doped n-type GaN layer at 1100 degrees Celsius after forming a buffer layer of AlN of 200 Å thickness at 400 degrees Celsius on a C-surface sapphire substrate. FIG. 2B is an atomic force microscope (AFM) image of a non-doped GaN layer (the second layer). The non-doped GaN layer is formed by forming a non-doped GaN layer at 900 degrees Celsius after forming a AlN buffer layer of 200 Å thickness at 400 degrees Celsius on a C-surface sapphire substrate and forming a silicon doped n-type GaN layer at 1100 degrees Celsius on the buffer layer. Both FIGS. 2A and 2B shows a 10 μm×10 μm square area.

In FIG. 2A, only countable pits are seen other than a large waving recess seen as a black area. In other word, since threading dislocations can not be observed with AFM in this magnification range, even if there are the threading dislocations, the threading dislocations have not been transformed into the pits.

On the other hand, in FIG. 2B, a large number of recesses can be observed on the surface of the GaN layer (the second layer), which is grown at relatively low temperature. The density of such recesses is 1000/100 μm² and the density is the same level as that of the threading dislocations. In other words, the pits are originated from the threading dislocations reaching the second layer through the first layer. Since the side surface of the pits are on the inclined surface, the opening of each pits expands while the layer thickness increases.

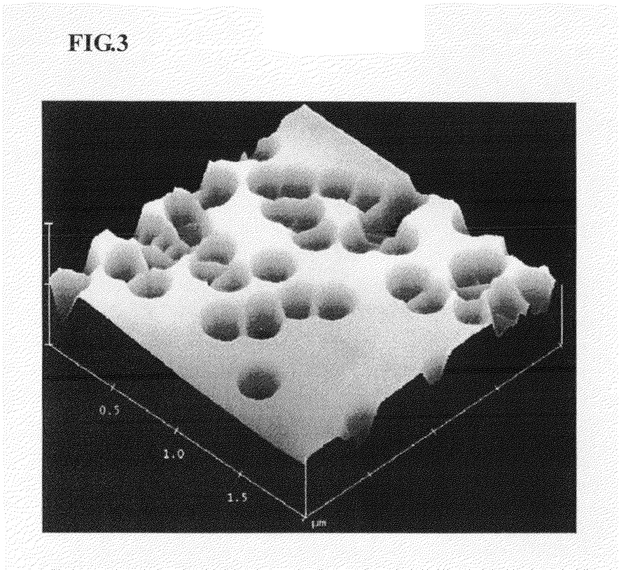

FIG. 3 is a bird's eye view of the GaN sample shown in the AFM image of FIG. 2B. The black large recesses observed in FIG. 2B have an inclined side surface, and the inclined side surface can be found to be (10-11) surface.

As described above, a large number of recesses can be formed on the surface of the second layer by epitaxially growing the second layer less than 1000 degrees Celsius, preferably 900 degrees Celsius, rather than 1000 to 1100 degrees Celsius which is said to be a temperature range to form a high quality single crystal. The recesses have a side surface of an inversed hexagonal cone and the side surface thereof is the (10-11) surface. Accordingly, it is facile to form a pit configured from a facet crossing the C-surface at other than 90 degrees.

Although FIGS. 2A, 2B and 3 show a case where the flat portion of the second layer is the C-surface and the facet is the (10-11) surface, it can be easily understood the situation is similar to a case where the flat portion of the second layer is not the C-surface, and a case where the pit is not configured from facets other than the (10-11) surface.

Next, the effect of the thickness of the buffer layer is examined.

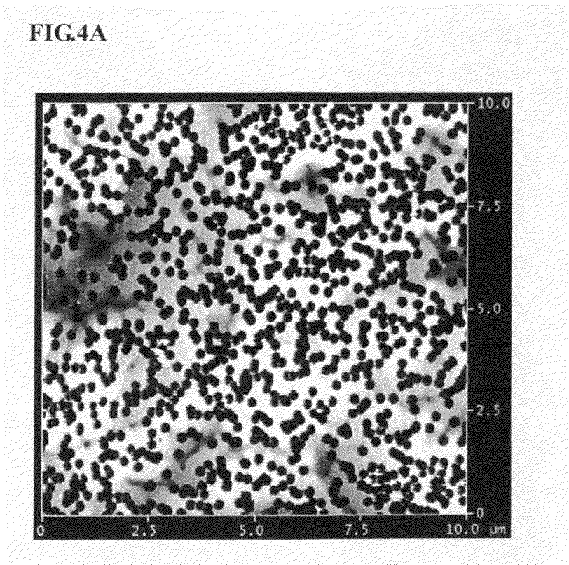

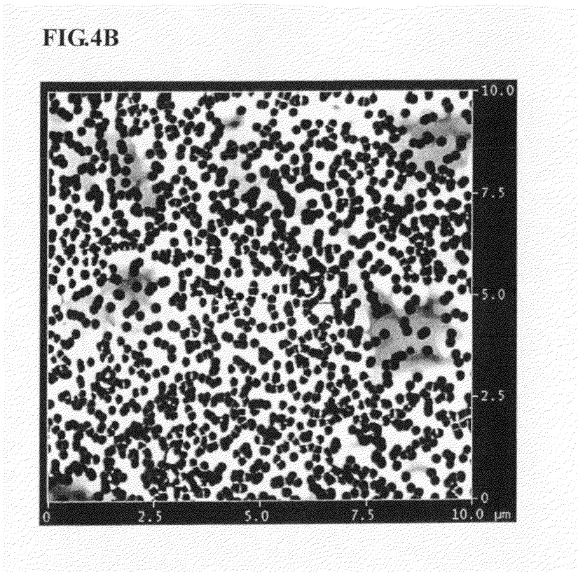

FIG. 4A is an atomic force microscope (AFM) image of a non-doped GaN layer (the second layer). The non-doped GaN layer is formed by forming a non-doped GaN layer after forming a MN buffer layer of 200 Å thickness at 400 degrees Celsius on the C-surface sapphire substrate and forming a silicon doped n-type GaN layer (the first layer) at 1100 degrees Celsius. FIG. 4B is an atomic force microscope (AFM) image of a non-doped GaN layer (the second layer). The non-doped GaN layer (the second layer) is formed by forming a non-doped GaN layer at 900 degrees Celsius after forming a AlN buffer layer of 300 Å at 400 degrees Celsius on the C-surface sapphire substrate and forming a silicon doped n-type GaN layer (the first layer) on the buffer layer. Both FIGS. 4A and 4B shows a 10 μm×10 μm square area.

The pits are observed with 1000/100 μm² density in FIG. 4A, and the twice of which are observed in FIG. 4B.

As comparing FIGS. 4A and 4B, it can be found that the number of the recess surrounded by the facets of the GaN layer as the second layer increases nearly twice while the buffer layer becomes thicker. The reason is that the thicker the buffer layer under the GaN layer is, the more increase the number of crystal defects which are originated from the facet surface at the beginning of the GaN layer epitaxial growth as the second layer. In other words, the core density of the crystal increased as the thickness of the bottom buffer layer increased.

Although FIGS. 4A and 4B show a case where the flat portion of the second layer is the C-surface and the facet is the (10-11) surface, it can be easily understood the situation is similar to a case where the flat portion of the second layer is not the C-surface, and a case where the pit is not configured from facets other than the (10-11) surface.

In the above explanation, although the case where the C-surface of the sapphire substrate is used is explained, the similar result is obtained in a case where the A-surface of the sapphire substrate is used.

### First Exemplary Embodiment

In consideration of above facts, a light emitting element which emits white color light is manufactured. The light emitting element emits white color light by emitting yellow color light in the C-surface of the luminescent layer, and emitting blue color light in the (10-11) facets of the luminescent layer.

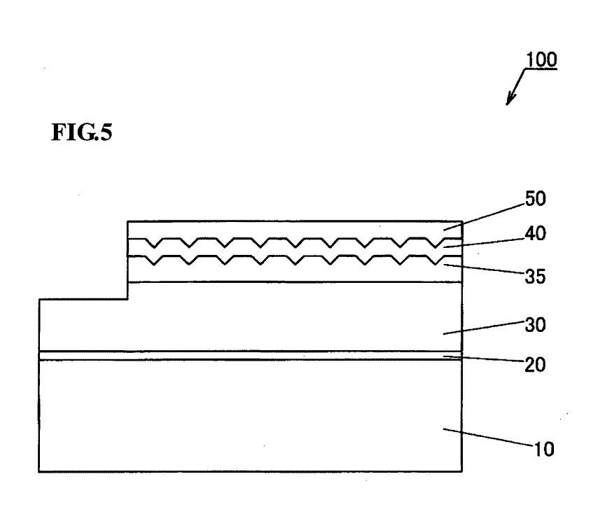

FIG. 5 is a cross sectional view of a group III nitride compound semiconductor light emitting element 100 of the first exemplary embodiment.

The group III nitride compound semiconductor light emitting element 100 comprises a C-surface sapphire substrate 10, a AlN buffer layer 20, a silicon doped n-type GaN layer 30 (the first layer), a non-doped GaN layer 35 (the second layer), a luminescent layer 40 of a multi quantum well structure, and a Mg doped p-type GaN layer 50 (the third layer). The MN buffer layer 20 is formed at 400 degrees Celsius in 300 Å thickness. The silicon doped n-type GaN layer 30 (the first layer) is formed at 1100 degrees Celsius in 4 μm. The non-doped GaN layer 35 (the second layer) is formed at 900 degrees Celsius in 300 nm. The luminescent layer 40 of a multi quantum well structure has a well layer of a non-doped In_{0.35}Ga_{0.65}N layer formed at 800 degrees Celsius in 3 nm thickness. The Mg doped p-type GaN layer 50 is formed at 1100 degrees Celsius in 200 nm thickness.

According to the below described luminescent spectrum, the composition of the well layer of the luminescent layer 40 of the multi quantum well structure seemed to change as substantially In_{0.15}Ga_{0.85}N on the facets of the non-doped GaN layer 35.

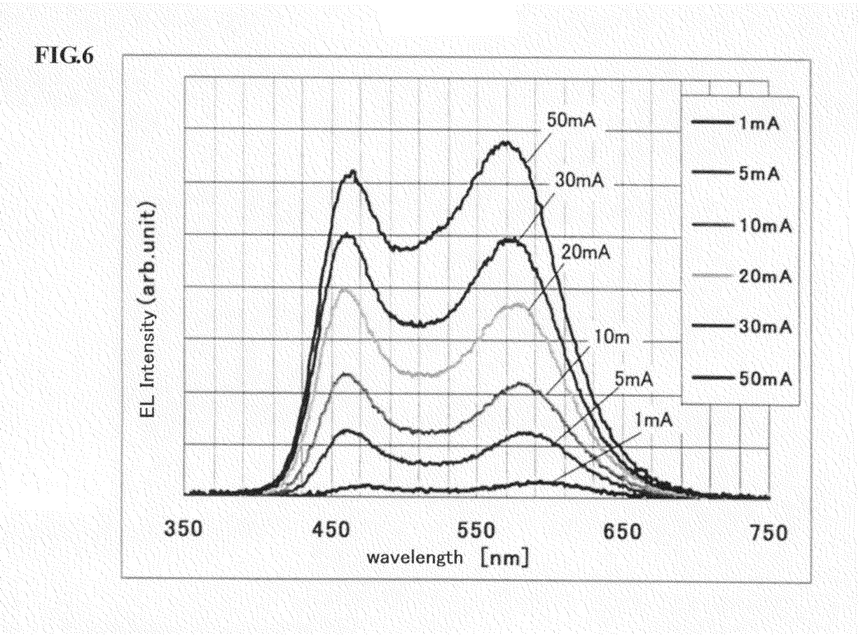

The luminescent spectrum of the group III nitride compound semiconductor light emitting element 100 is shown in FIG. 6. The luminescent spectrum is plotted while the injection current is changed in 6 stages: 1 mA, 5 mA, 10 mA, 20 mA, 30 mA, and 50 mA.

The luminescent spectrum of the group III nitride compound semiconductor light emitting element 100 shows its peak at 465 nm wavelength and 570 nm wavelength, and an enough strong intensity and a quite broad range within visible wavelength. This result shows that the composition of the well layer of the multi quantum well structure of the luminescent layer 40 smoothly changes from the upper portion of the C-surface of the GaN layer 35 to the upper portion of the facet. Also, the chromaticity coordinate (x, y) is (0.3171, 0.3793).

In the luminescent spectrum of FIG. 6, a half value width can be obtained as below. In a case where the injection current is 50 mA, the range of the wavelength where the luminescence intensity is half of the 570 nm peak is 440 nm to 610 nm and the half value width is 170 nm. The half value widths are also substantially 170 nm for another injection current value. In a case where a light emitting element is formed without the non-doped GaN layer (the second layer) 35 which is formed at 900 degrees Celsius in 300 nm thickness, there is a single peak at 570 nm in its luminescent spectrum and the half value width is 80 nm.

In the luminescent spectrum of FIG. 6, the two peak wavelengths are 465 nm and 570 nm, and the difference therebetween is 105 nm. Also the ratio of the luminescence intensity of 465 nm wavelength to the luminescence intensity of 570 nm wavelength is 0.9 to 1.1 within the range of the injection current equal to or more than 1 mA and equal to or less than 50 mA.

That is, the group III nitride compound semiconductor light emitting element 100 of the first exemplary embodiment is a white color light emitting element with high color rendering property, which has an enough luminescence intensity within a quite broad range of visible wavelength and the whiteness of the luminescence is very high.

In order to obtain an expanded luminescent spectrum like above, it is preferable to make the composition of indium in the luminescent layer 0.05 to 0.5, more preferably 0.3 to 0.5. The thickness of the luminescent layers in each well layer is preferably 1 to 10 nm. Also, the growth temperature is preferably 600 to 900 degrees Celsius.

Although the above described first exemplary embodiment shows a case where the flat portion of the second layer is the C-surface and the pits are formed from (10-11) facets, a case where the flat portion of the second layer is not the C-surface and a case where the pits are formed from other than (10-11) facets are similar. In other words, the essential point of the exemplary embodiment of the present invention is that the threading dislocations, which is originated from the buffer layer and reaches the second layer through the first layer, is changed into pits, whose cross sections parallel to the substrate expands in the growth direction in the second layer, when the substrate, the buffer layer, the first layer, and the second layer are formed in this order. In this point, the flat portion of the second layer is not limited to the C-surface, and the facets of the pits are not limited to the (10-11) surface.

In the above described first exemplary embodiment, although a white color light emitting element whose luminescent spectrum has a peak at the blue color range and the yellow color range respectively, the exemplary embodiment of the present invention can be applied for arbitrary color light emitting elements whose luminescent spectrum has an expanded spectrum width relative to the luminescent spectrum of a case where there is no pits. For example, a light emitting element, whose luminescent spectrum expands in the green color range and the red color range, can be formed as same as the above describe exemplary embodiment by modifying the supply of indium during formation of the luminescent layer.

The ratio of luminescence intensity of the long wavelength side to the short wavelength side in the two peaks can be easily controlled by the ratio of the area size of the flat portion to that of the pits. The control of the ratio of luminescence intensity is the control of the number of the origin of the threading dislocations at the time of forming the buffer layer and the control of the area size of each pit by controlling the thickness of the second layer.

While the present invention has been shown and described with reference to certain exemplary embodiments thereof, it will be understood by those skilled in the art that various changes in form and details may be made therein without departing from the spirit and scope of the invention as defined by the appended claims.

1. A group III nitride compound semiconductor light emitting element, which having a luminescent layer formed from a group III nitride compound semiconductor containing at least indium, comprising:
a substrate;
a buffer layer formed on the substrate;
a first layer which is a single crystal layer of a group III nitride compound semiconductor, the first layer formed on the buffer layer and including a threading dislocation;
a second layer of a group III nitride compound semiconductor formed on the first layer, the second layer including a pit and a flat portion, wherein the pit continuing from the threading dislocations, formed during the second layer growth, and having a cross section parallel to the substrate expanding in a growth direction of the second layer;
a luminescent layer formed on the second layer while along the pit of the second layer and the flat portion of the second layer so as to form a flat portion and a pit, and an indium concentration in the pit of the luminescent layer smaller than an indium concentration in the flat portion of the luminescent layer;
a third layer of a group III nitride compound semiconductor formed on the luminescent layer; and
a luminescent spectrum whose width is expanded as compared to a case where the pit does not exist.

2. The group III nitride compound semiconductor light emitting element according to claim 1, wherein the luminescent spectrum has at least two peaks.

3. The group III nitride compound semiconductor light emitting element according to claim 1, wherein the second layer is gallium nitride.

4. The group III nitride compound semiconductor light emitting element according to claim 1, wherein a principal surface of the flat portion of the second layer is a C-surface, a side surface forming the pit is a facet crossing the C-surface at other than normal angle.

5. The group III nitride compound semiconductor light emitting element according to claim 4, wherein the facet is a (10-11) surface.

6. The group III nitride compound semiconductor light emitting element according to claim 1, wherein the flat portion of the luminescent layer emits green or red color light, and the pit of the luminescent layer emits purple or blue light.

7. The group III nitride compound semiconductor light emitting element according to claim 1, wherein a luminescence color of the luminescent layer is white.

8. A manufacturing method of a group III nitride compound semiconductor light emitting element, which having an luminescent layer formed from a group III nitride compound semiconductor including at least indium, comprising:
forming a buffer layer on a substrate;
forming a first layer on the buffer layer, the first layer being a single crystal layer of a group III nitride compound semiconductor, and including a threading dislocations;
forming a second layer of a group III nitride compound semiconductor including a pit and a flat portion, the pit continuing from the threading dislocations, a cross section of the pit parallel to the substrate expanding in a growth direction of the second layer;
forming an luminescent layer on the second layer while along the flat portion of the second layer and the pit of the second layer, the luminescent layer including a flat portion and a pit;
expanding a luminescent spectrum width as compare to a luminescent spectrum width of a case where pit does not exist by reducing a indium density in the pit of the luminescent layer as compared to a indium density in the flat portion of the luminescent layer; and
forming a third layer of a group III nitride compound semiconductor on the luminescent layer.

9. The manufacturing method of a group III nitride compound semiconductor light emitting element according to claim 8, wherein a growth temperature of the second layer is equal to or less than 1000 degrees Celsius.

10. The manufacturing method of a group III nitride compound semiconductor light emitting element according to claim 9, wherein the second layer is gallium nitride.

11. The manufacturing method of a group III nitride compound semiconductor light emitting element according to claim 10, wherein a growth temperature of the luminescent layer is equal to or higher than 600 degrees Celsius and is equal to or less than 900 degrees Celsius.
